(19) United States
(12) Patent Application Publication
(10) Pub. No.: US 2026/0344374 A1
(43) Pub. Date: Oct. 29, 2026

(54) HETEROGENEOUS SEMICONDUCTOR STRUCTURE AND METHOD FOR PRODUCING THE SAME

(71) Applicants: Materials Analysis Technology Inc., Hsinchu County (TW); National Yang Ming Chiao Tung University, Hsinchu City (TW)

(72) Inventors: Umeshwar Reddy Nallasani, Hsinchu City (TW); Wu-Ching Chou, Hsinchu City (TW); HUNG-JEN CHEN, Hsinchu City (TW)

(21) Appl. No.: 19/630,535

(22) Filed: Mar. 27, 2026

Related U.S. Application Data
(60) Provisional application No. 63/794,759, filed on Apr. 25, 2025.

(51) Int. Cl. H10P 90/00; H10P 14/20; H10P 14/22; H10W 10/10

(52) U.S. Cl. CPC H10P 90/1912; H10P 14/22; H10P 14/2921; H10P 14/3234; H10P 14/3436; H10W 10/181

(57) ABSTRACT

A heterogeneous semiconductor structure applicable to optical applications and a method for manufacturing the same. The method includes using a vacuum epitaxy system to epitaxially form a first epitaxial film composed of a three-dimensional semiconductor material on a substrate under a vacuum condition, and epitaxially forming a second epitaxial film composed of a two-dimensional semiconductor material on the first epitaxial film within the same vacuum epitaxy system while maintaining and without breaking the vacuum condition. The substrate is an oxide single-crystal substrate, the three-dimensional semiconductor material is an N-type semiconductor material having a three-dimensional crystal structure, and the two-dimensional semiconductor material is a P-type semiconductor material having a multilayer layered crystal structure.

### CROSS-REFERENCE TO RELATED PATENT APPLICATION

This application claims the benefit of priority to the U.S. Provisional Patent Application Ser. No. 63/794,759, filed on Apr. 25, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor structure, and more particularly to a heterogeneous semiconductor structure applicable to optical applications and a method for manufacturing the same.

### BACKGROUND OF THE DISCLOSURE

In the technical field of heterogeneous semiconductor structures, integrating different types or lattice structures of semiconductor materials within a single device has great potential to realize applications in optoelectronic devices, such as photodetectors.

However, in the related art, lattice mismatch or poor epitaxial quality between heterogeneous materials often leads to interfacial defects during the epitaxial growth process, such as interlayer dislocations, voids, interfacial discontinuities, or chemical contamination. These issues degrade carrier transport efficiency, interfacial stability, and overall device performance. Particularly, when performing heterogeneous epitaxy, controlling the interface quality remains a technical challenge. Therefore, there is a demand in the industry for achieving high-quality, reproducible, and process-scalable heterogeneous semiconductor structures.

### SUMMARY OF THE DISCLOSURE

In response to the above-referenced technical inadequacies, the present disclosure provides a heterogeneous semiconductor structure and a method for manufacturing the same for optical applications.

In order to solve the above-mentioned problems, one of the technical aspects adopted by the present disclosure is to provide a method for manufacturing a heterogeneous semiconductor structure, which includes performing a first epitaxy process including epitaxially forming a first epitaxial film composed of a three-dimensional semiconductor material on a substrate under a vacuum condition ranging from 10⁻¹² Torr to 10⁻⁷ Torr using a vacuum epitaxy system. The substrate is an oxide single-crystal substrate, and the three-dimensional semiconductor material is an N-type semiconductor material having a three-dimensional crystal structure. The method further includes performing a second epitaxy process including epitaxially forming a second epitaxial film composed of a two-dimensional semiconductor material on the first epitaxial film within the vacuum epitaxy system while maintaining and without breaking the vacuum condition. The two-dimensional semiconductor material is a P-type semiconductor material having a multilayer layered crystal structure.

In order to solve the above-mentioned problems, another one of the technical aspects adopted by the present disclosure is to provide a heterogeneous semiconductor structure including a substrate, a first epitaxial film, and a second epitaxial film. The substrate is an oxide single-crystal substrate. The first epitaxial film is formed on the substrate and composed of a three-dimensional semiconductor material, in which the three-dimensional semiconductor material is an N-type semiconductor material having a three-dimensional crystal structure. The second epitaxial film is formed on the first epitaxial film and composed of a two-dimensional semiconductor material, in which the two-dimensional semiconductor material is a P-type semiconductor material having a multilayer layered crystal structure.

Therefore, through the above technical approach, the present disclosure effectively improves the interface cleanliness and epitaxial quality between the two-dimensional and three-dimensional materials in the heterogeneous semiconductor structure. Compared with conventional transfer or exfoliation stacking methods, the method of the present embodiment significantly reduces interface defect density and enhances the bonding integrity of the heterogeneous structure. Furthermore, the embodiment of the present disclosure achieves a high-quality heterogeneous junction structure, which provides excellent electrical stability and photoresponse performance for subsequent optoelectronic applications, such as self-powered photodetectors.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic flow diagram illustrating a method for manufacturing a heterogeneous semiconductor structure according to a first embodiment of the present disclosure;

FIG. 2A is a schematic view illustrating the formation of a first epitaxial layer according to the first embodiment of the present disclosure;

FIG. 2B is a schematic view illustrating the formation of a second epitaxial layer according to the first embodiment of the present disclosure;

FIG. 3 is a schematic flow diagram illustrating a method for manufacturing a heterogeneous semiconductor structure according to a second embodiment of the present disclosure;

FIG. 4A is a schematic view illustrating the formation of a metal-terminated layer according to the second embodiment of the present disclosure;

FIG. 4B is a schematic view illustrating the formation of a non-metal passivation layer according to the second embodiment of the present disclosure;

FIG. 5A is a schematic view illustrating the heterogeneous semiconductor structure according to the second embodiment of the present disclosure;

FIG. 5B is an enlarged partial schematic view of region VB in FIG. 5A;

FIG. 6 shows the in-situ reflection high-energy electron diffraction (RHEED) analysis results of the embodiments of the present disclosure (for samples S1 to S3);

FIG. 7 shows the photoluminescence (PL) analysis results of the embodiments of the present disclosure (for samples S1 to S3);

FIG. 8 shows the high-resolution transmission electron microscopy (HRTEM) analysis image of the heterogeneous semiconductor structure of the embodiments of the present disclosure (for sample S3); and

FIG. 9 is a high-magnification image of the heterogeneous semiconductor structure shown in FIG. 8.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

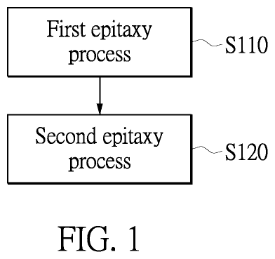

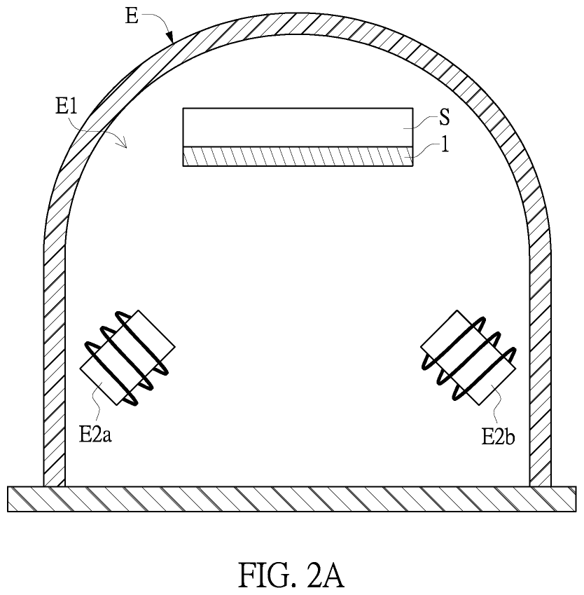

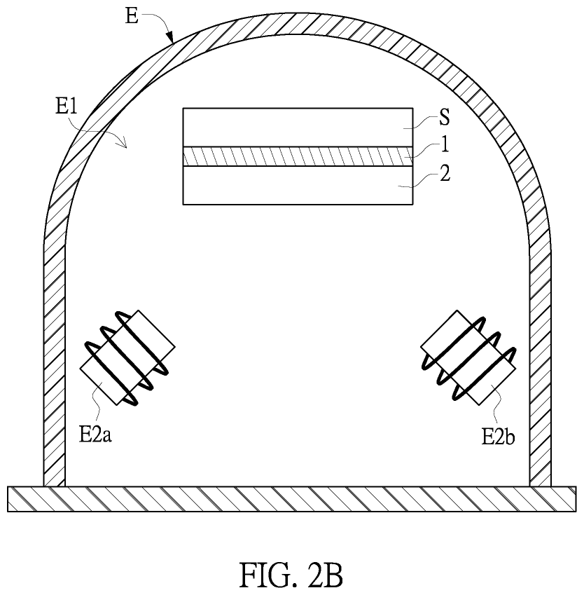

Referring to FIG. 1, FIG. 2A, and FIG. 2B, a first embodiment of the present disclosure provides a method for manufacturing a heterogeneous semiconductor structure, which includes step S110 (first epitaxy process) and step S120 (second epitaxy process).

### First Epitaxy Process

As shown in FIG. 2A, step S110 is to perform a first epitaxy process, which includes using a vacuum epitaxy system E to epitaxially form a first epitaxial film 1 composed of a three-dimensional semiconductor material on a substrate S under a vacuum condition.

The vacuum epitaxy system E can be, for example, a molecular beam epitaxy (MBE) system. More specifically, the vacuum epitaxy system E is a system used for epitaxial growth of semiconductor materials, in which atoms or molecules are deposited on a surface of the substrate S under an ultra-high-vacuum environment to form an epitaxial film(s).

In some embodiments, the vacuum condition is achieved inside a vacuum chamber E1 of the vacuum epitaxy system E. The operating pressure range of the vacuum condition is about 10⁻¹² Torr to 10⁻⁷ Torr, preferably 10⁻¹¹ Torr to 10⁻⁸ Torr, and more preferably 10⁻¹¹ Torr to 10⁻⁹ Torr.

In some embodiments, the substrate S is a single-crystal substrate having electrical insulation. Preferably, the substrate S is a sapphire single-crystal substrate, such as a c-plane sapphire substrate. The sapphire single-crystal substrate is formed of single-crystal aluminum oxide (α-Al₂O₃), but the present disclosure is not limited thereto. The substrate S can also be another oxide single-crystal substrate, for example, a strontium titanate (SrTiO₃) single-crystal substrate, a lanthanum aluminate (LaAlO₃) single-crystal substrate, or a magnesium oxide (MgO) single-crystal substrate.

The three-dimensional semiconductor material is an N-type semiconductor material having a three-dimensional crystal structure, which can be intrinsic or doped to exhibit N-type conductivity. The three-dimensional semiconductor material can serve as a three-dimensional carrier layer in the heterogeneous semiconductor structure and provides a high breakdown electric field, high thermal stability, and the capability to form a semiconductor heterojunction with a two-dimensional material.

In the present embodiment, the three-dimensional semiconductor material is gallium oxide (Ga₂O₃), and is particularly n-type β-gallium oxide (n-type β-Ga₂O₃), but the present disclosure is not limited thereto. The N-type three-dimensional semiconductor material can also be another suitable metal oxide, such as indium oxide (In₂O₃) or zinc oxide (ZnO).

In terms of physical properties, the three-dimensional semiconductor material has a first bandgap ranging from 2.8 eV to 5.0 eV, and preferably from 4.8 eV to 5.0 eV, and the three-dimensional semiconductor material has a first in-plane lattice constant along a b-axis direction ranging from 2.8 Å to 3.3 Å.

### Second Epitaxy Process

As shown in FIG. 2B, step S120 is to perform a second epitaxy process, which includes epitaxially forming a second epitaxial film 2 composed of a two-dimensional semiconductor material on the first epitaxial film 1 within the vacuum epitaxy system E while maintaining and without breaking the vacuum condition in the first epitaxy process.

In other words, the first epitaxial film 1 and the second epitaxial film 2 are sequentially formed in the same vacuum chamber E1 of the vacuum epitaxy system E (i.e., a molecular beam epitaxy system) without breaking the vacuum condition.

The two-dimensional semiconductor material is a P-type semiconductor material having a two-dimensional layered crystal structure. In other words, the second epitaxial film 2 is formed as a multilayer layered structure composed of a two-dimensional semiconductor material, in which each layer is formed by covalent bonding, and the layers are bound to each other by van der Waals forces.

In some embodiments, the two-dimensional semiconductor material is gallium selenide (GaSe), and is particularly a layered gallium selenide structure that intrinsically exhibits P-type conductivity. The two-dimensional semiconductor material has lattice matching compatibility when forming a heterojunction with the above-mentioned three-dimensional semiconductor material. For example, the in-plane lattice constant (along the b-axis direction) of GaSe (about 3.785 Å) and that of β-Ga₂O₃ (about 3.04 Å) have a relative difference of less than 25%. In addition, the two-dimensional semiconductor material has a second bandgap ranging from 1.9 eV to 2.1 eV, which is suitable for photoelectric applications in the visible region.

In other embodiments, the two-dimensional semiconductor material can also be a layered semiconductor having properties similar to gallium selenide, such as molybdenum disulfide (MoS₂), molybdenum diselenide (MoSe₂), molybdenum ditelluride (MoTe₂), tungsten disulfide (WS₂), tungsten diselenide (WSe₂), or tungsten ditelluride (WTe₂).

The above two-dimensional semiconductor materials can be selected based on application requirements, and the number of layers, thickness, and growth temperature can be further adjusted to optimize carrier transport efficiency, band alignment, and photo-response characteristics in the heterogeneous structure.

### Second Embodiment

The above embodiment involves performing the first epitaxy process (step S110) and the second epitaxy process (step S120) sequentially on the substrate S to form the first epitaxial film 1 and the second epitaxial film 2.

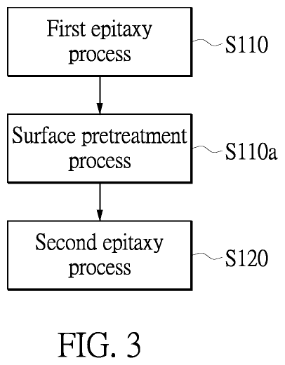

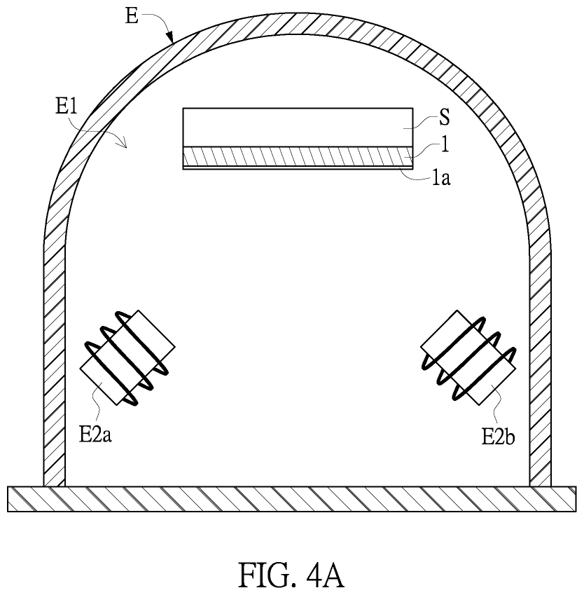

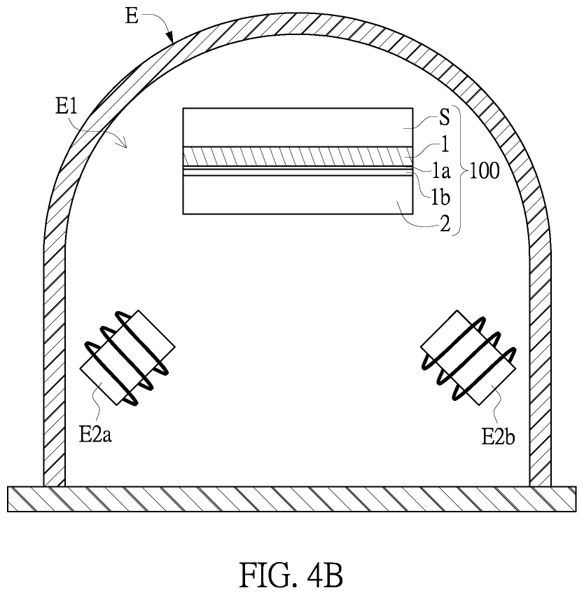

Referring to FIG. 3, FIG. 4A, and FIG. 4B, the embodiment of the present disclosure also provides a method for manufacturing a heterogeneous semiconductor structure, which includes a first epitaxy process (step S110), a surface pretreatment process (step S110a), and a second epitaxy process (step S120). The main difference between the second embodiment and the above first embodiment is that the method of the second embodiment further includes performing the surface pretreatment process (step S110a) between the first epitaxy process (step S110) and the second epitaxy process (step S120).

### Surface Pretreatment Process

Specifically, as shown in FIG. 4A, the surface pretreatment process includes: after the first epitaxy process (step S110), performing, an atomic-level metal evaporation deposition pretreatment on the first epitaxial film 1 formed on the substrate S through a metal source E2a, so as to form a metal-terminated layer 1a on a surface of the first epitaxial film 1 to promote nucleation and growth of the two-dimensional semiconductor material in the subsequent second epitaxy process (step S120). In other words, the metal-terminated layer 1a can alter the surface free energy of the first epitaxial film 1, shortens the nucleation delay of the subsequent two-dimensional semiconductor material, and suppresses interface defect generation. It is worth noting that the surface pretreatment process is also performed in the vacuum epitaxy system E while maintaining the vacuum condition (without breaking the vacuum condition).

In the atomic-level metal evaporation deposition pretreatment, the metal atoms supplied from the metal source E2a are identical or compatible with at least one metal element contained in the three-dimensional semiconductor material, such as chemically compatible metal elements including gallium, indium, or aluminum.

For example, when the three-dimensional semiconductor material of the first epitaxial film 1 is gallium oxide (Ga₂O₃), the metal atoms used in the atomic-level metal evaporation deposition pretreatment can be gallium (Ga). The gallium atoms can bond with surface oxygen atoms in the first epitaxial film 1 and form a gallium metal-terminated surface, thereby promoting nucleation and layered stacking of the subsequent two-dimensional semiconductor material.

In other embodiments, the metal atoms used in the atomic-level metal evaporation deposition pretreatment can be selected from the metal element identical or chemically compatible with the main-group metal element of the three-dimensional semiconductor material, such as indium (In), aluminum (Al), or zinc (Zn), which depends on the material system and interfacial engineering requirements.

Then, as shown in FIG. 4B, the second epitaxy process (step S120) further includes forming the second epitaxial film 2 composed of the two-dimensional semiconductor material on the metal-terminated layer 1a formed on the surface of the first epitaxial film 1. It is worth noting that during the epitaxy process of the second epitaxial film 2, such as GaSe, the flux of the non-metal source E2b (e.g., selenium Se atomic beam) is set significantly higher than that of the metal source E2a (e.g., gallium Ga atomic beam) to create a selenium-rich environment (Se rich environment). The selenium-rich environment helps increase the surface selenium atom concentration, thereby promoting the reaction between selenium and the surface of the metal-terminated layer 1a, such as gallium layer, to form a continuous and stable non-metal passivation layer (e.g., selenium Se passivation layer), which enhances the interface quality and epitaxial stability of the heterogeneous structure. The two-dimensional semiconductor material reacts with the metal-terminated layer 1a to form a non-metal passivation layer 1b between the first epitaxial film 1 and the second epitaxial film 2. The non-metal passivation layer 1b is formed on the metal-terminated layer 1a.

The non-metal element contained in the non-metal passivation layer 1b is identical to the non-metal element contained in the two-dimensional semiconductor material.

For example, when the two-dimensional semiconductor material of the second epitaxial film 2 is gallium selenide (GaSe), the non-metal element contained in the non-metal passivation layer 1b is selenium (Se), which originates from the non-metal element of the two-dimensional semiconductor material. The non-metal element reacts with the metal element of the metal-terminated layer 1a on the surface of the first epitaxial film 1, such as the reaction between selenium and gallium, to form the non-metal passivation layer, (e.g., a selenium passivation layer).

The non-metal passivation layer 1b has a single-layer or sub-single-layer thickness and exists between the first epitaxial film 1 and the second epitaxial film 2. This configuration helps maintain the interlayer stacking characteristics of the two-dimensional layered material and enhances the integration stability of the heterogeneous epitaxy.

In other embodiments, when the two-dimensional semiconductor material of the second epitaxial film 2 is another layered semiconductor material having properties similar to gallium selenide, such as molybdenum disulfide (MoS₂), molybdenum diselenide (MoSe₂), molybdenum ditelluride (MoTe₂), tungsten disulfide (WS₂), tungsten diselenide (WSe₂), or tungsten ditelluride (WTe₂), the non-metal element contained in the non-metal passivation layer 1b corresponds to the main-group anionic element of the two-dimensional semiconductor material. For example, the non-metal element can be selenium (Se), sulfur (S), or tellurium (Te).

The above non-metal element can form bonds with the metal element, such as gallium, of the metal-terminated layer 1a formed on the surface of the first epitaxial film 1 during the epitaxy process, thereby forming a stable non-metal passivation layer 1b. This promotes the bonding integrity of the heterojunction and reduces the interface defect density.

In other words, the non-metal element can be an element belonging to Group VIA of the periodic table, including but not limited to selenium (Se), sulfur (S), and tellurium (Te). These elements can form stable chemical bonds with the metal element of the metal-terminated layer, such as gallium (Ga) or indium (In), which helps construct a high-quality mixed-dimensional two-dimensional and three-dimensional heterogeneous structure.

The processes of the first epitaxy process, the second epitaxy process, and the surface pretreatment process have been described above. The following describes the detailed process flow and manufacturing conditions of these processes.

### Details and Process Conditions of the First Epitaxy Process

Referring to FIG. 1 and FIG. 2A, the first epitaxy process (step S110) includes epitaxially forming a first epitaxial film 1 composed of a three-dimensional semiconductor material on the substrate S.

In some embodiments of the present disclosure, the first epitaxy process adopts a plasma-assisted molecular beam epitaxy (PA-MBE) system for epitaxial growth. The PA-MBE system includes an ultra-high-vacuum chamber E1 that provides an atomically clean environment. The operating pressure of the vacuum condition ranges from about 10⁻¹¹ Torr to about 10⁻⁸ Torr, preferably from about 10⁻¹¹ Torr to 10⁻⁹ Torr, and more preferably about 10⁻¹⁰ Torr.

In the epitaxy process, the first epitaxy process includes adopting a single-crystal substrate having electrical insulation, preferably a sapphire single-crystal substrate composed of single-crystal aluminum oxide (α-Al₂O₃). In addition, other insulating oxide single-crystal substrates having lattice matching with the subsequent three-dimensional semiconductor material can also be used, such as a strontium titanate (SrTiO₃) single-crystal substrate, a lanthanum aluminate (LaAlO₃) single-crystal substrate, or a magnesium oxide (MgO) single-crystal substrate.

In the present embodiment, the first epitaxial film 1 is formed by epitaxial growth of a three-dimensional N-type semiconductor material, which is β-phase gallium oxide (β-Ga₂O₃). The β-Ga₂O₃ material has an ultra-wide bandgap (about 4.8 to 5.0 eV), a high breakdown electric field, and high thermal stability, which is suitable for being used as a substrate layer for subsequent epitaxial growth of a two-dimensional semiconductor material.

The process conditions of the first epitaxy process include heating the substrate S to a first epitaxy temperature between about 400 °C and 500 °C, preferably between 425 °C and 475 °C, and more preferably about 450 °C. The heating rate to the first epitaxy temperature is about 5 °C/min to 20 °C/min, preferably about 10 °C/min. Subsequently, a radio-frequency (RF) oxygen plasma source of the molecular beam epitaxy system is used to activate oxygen. The RF power is about 250 W to 350 W, preferably about 300 W, and the oxygen gas flow rate is about 0.5 sccm to 2 sccm, preferably about 1 sccm. The metal source E2a of the vacuum epitaxy system E uses a gallium (Ga) atomic source, with a metal atomic flux (Ga flux) ranging from about 1.0×10⁻⁸ Torr to 5.0×10⁻⁸ Torr, preferably about 2.0×10⁻⁸ Torr, to control the film thickness and composition.

Under the above conditions, an epitaxy time of about 30 minutes to 120 minutes, preferably about 45 minutes to 75 minutes, and more preferably about 55 minutes to 65 minutes (e.g., 60 minutes), allows formation of the first epitaxial film 1, such as a β-Ga₂O₃ film layer, on the surface of the substrate S. The thickness of the first epitaxial film 1 is about 20 nm to 50 nm, preferably about 30 nm to 35 nm. Subsequently, the temperature of the substrate S is decreased at a cooling rate of about 10 °C/min to 30 °C/min, preferably about 20 °C/min, to a first cooling temperature of about 20 °C to 80 °C. The epitaxy process can be monitored in real time by reflection high-energy electron diffraction (RHEED) in the vacuum epitaxy system E, such as PA-MBE, to observe the epitaxial growth behavior and surface crystallinity.

For example, the formed β-Ga₂O₃ film layer exhibits a clear epitaxial orientation along the (^{2̅}01) crystal plane direction. The in-plane lattice constant along the b-axis direction ranges from about 2.8 Å to 3.3 Å, preferably from about 3.0 Å to 3.1 Å, and more preferably about 3.04 Å. The surface roughness (RMS roughness) of the β-Ga₂O₃ film layer (i.e., the first epitaxial film 1) is less than 1 nm, preferably less than 0.8 nm, and more preferably about 0.56 nm.

The first epitaxy process described above effectively provides a three-dimensional N-type semiconductor base layer with atomic-level cleanliness, low defect density, high crystal quality, and stable surface characteristics. The base layer facilitates subsequent nucleation, growth, and interfacial engineering of the two-dimensional semiconductor material, thereby forming a mixed-dimensional heterogeneous semiconductor structure with excellent optoelectronic properties.

### Details and Process Conditions of the Surface Pretreatment Process

Referring to FIG. 3, FIG. 4A, and FIG. 4B, as described above, the method for manufacturing the heterogeneous semiconductor structure can optionally include performing a surface pretreatment process (step S110a) between the first epitaxy process (step S110) and the second epitaxy process (step S120). Specifically, the surface pretreatment process is performed inside the vacuum chamber E1 of the vacuum epitaxy system E while continuously maintaining the vacuum condition, that is, without breaking the vacuum environment.

The surface pretreatment process includes two main steps of: a metal atom evaporation deposition step (i.e., an atomic-level metal evaporation deposition pretreatment) and a subsequent annealing step. In the metal atom evaporation deposition step, the substrate S is first heated from the above-mentioned first cooling temperature (e.g., 20 °C to 80 °C) to an evaporation deposition temperature of about 380 °C to about 460 °C, preferably about 400 °C to about 450 °C, and more preferably about 420 °C to about 430 °C (e.g., 425 °C). Then, the metal source E2a is activated to perform atomic evaporation deposition for about 1 minute to 10 minutes, preferably about 3 minutes to 7 minutes, and more preferably about 4 minutes to 6 minutes (e.g., 5 minutes). The metal atom flux (e.g., Ga flux) used during the atomic evaporation deposition step ranges from about 1.0×10⁻⁸ Torr to 8.0×10⁻⁸ Torr, preferably from about 3.0×10⁻⁸ Torr to 6.0×10⁻⁸ Torr, and more preferably from about 4.0×10⁻⁸ Torr to 5.0×10⁻⁸ Torr (e.g., 4.5×10⁻⁸ Torr).

The metal atoms used in the metal source E2a during the above metal atom evaporation deposition step can be identical or chemically compatible with at least one metal element of the three-dimensional semiconductor material, for example but not limited to gallium (Ga), indium (In), or aluminum (Al). For example, when the three-dimensional semiconductor material of the first epitaxial film 1 is gallium oxide (Ga₂O₃), the selected metal atom is gallium (Ga).

Subsequently, the annealing step is performed by increasing the temperature of the substrate S from the evaporation deposition temperature (e.g., about 425 °C) to an annealing temperature ranging from about 550 °C to 650 °C, preferably about 580 °C to 620 °C, and more preferably about 600 °C at a rate of about 10 °C/min to 20 °C/min. The annealing temperature is maintained for about 5 minutes to 15 minutes, preferably about 8 minutes to 12 minutes (e.g., 10 minutes). Then, the substrate S is cooled from the annealing temperature to the second epitaxy temperature of the subsequent second epitaxy process (e.g., about 425 °C to 440 °C) at a cooling rate of about 10 °C/min to 30 °C/min.

Through the metal atom evaporation deposition and subsequent annealing steps, the surface of the first epitaxial film 1 is effectively transformed from an oxygen-terminated surface to a metal-terminated surface, forming a metal-terminated layer 1a. This transformation can be observed in real time using reflection high-energy electron diffraction (RHEED), in which the diffraction pattern changes from a continuous pattern to a spotty pattern with a slight variation in spacing, confirming the occurrence of surface reconstruction and strain relaxation.

The formation of the metal-terminated layer 1a effectively alters the surface free energy of the first epitaxial film 1, thereby improving the nucleation condition of the subsequent two-dimensional semiconductor material on the surface and significantly shortening the nucleation delay time. Experimental observations show that, for a two-dimensional semiconductor material such as GaSe, the nucleation delay time on the pretreated surface can be reduced from about 15 minutes to less than 1 minute. The pretreatment also improves the uniformity of nucleation, film thickness, and surface coverage of the subsequent second epitaxial film 2 (e.g., a GaSe layered film), preventing interlayer dislocation and ensuring excellent structural quality and optoelectronic performance of the heterogeneous interface.

### Details and Process Conditions of the Second Epitaxy Process

Referring to FIG. 2B or FIG. 4B, the second epitaxy process (step S120) includes epitaxially forming a second epitaxial film 2 composed of a two-dimensional semiconductor material on the first epitaxial film 1 (or on the metal-terminated layer 1a), thereby forming a mixed-dimensional heterogeneous semiconductor structure.

In some embodiments of the present disclosure, the second epitaxy process can be performed directly after the first epitaxy process (as in the first embodiment, FIG. 1 and FIG. 2B); or can be optionally performed after a surface pretreatment process before proceeding (as in the second embodiment, FIG. 3 and FIG. 4B). Regardless of whether the surface pretreatment process is performed, the second epitaxy process is carried out in the same vacuum chamber E1 of the vacuum epitaxy system E while continuously maintaining the ultra-high-vacuum condition without breaking the vacuum environment.

In the second epitaxy process, the substrate S is heated from the above-mentioned first cooling temperature (e.g., 20 °C to 80 °C) to a second epitaxy temperature ranging from about 410 °C to 490 °C (e.g., the condition in which the second epitaxy process is directly performed after the first epitaxy process as described in the first embodiment). The preferred range of the second epitaxy temperature is about 410 °C to 440 °C, and more preferably about 425 °C. The heating rate heated to the second epitaxy temperature is about 5 °C/min to 20 °C/min, preferably about 8 °C/min to 15 °C/min, and more preferably about 10 °C/min. Alternatively, in the case of the second embodiment in which the second epitaxy process is performed after the surface pretreatment process, the substrate S is cooled from the above annealing temperature (e.g., 550 °C to 650 °C) down to the second epitaxy temperature at a cooling rate of about 10 °C/min to 30 °C/min. The above temperature conditions for the second epitaxy process are designed to effectively suppress the formation of secondary phases (e.g., Ga₂Se₃ phase) and ensure a high-purity crystalline phase of the second epitaxial film 2 (e.g., a GaSe layered film). The second epitaxy temperature range of about 410 °C to 440 °C provides better suppression of secondary phase formation, whereas higher temperatures (e.g., above 480 °C) can cause longer nucleation delay times.

In the second epitaxy process, when the temperature of the substrate S reaches the second epitaxy temperature (e.g., 425 °C to 440 °C), the metal source E2a (e.g., a gallium atomic beam source) and the non-metal source E2b (e.g., a selenium atomic beam source) of the molecular beam epitaxy system are successively activated to perform epitaxy. The flux range of the metal source E2a is about 2.0×10⁻⁸ Torr to 8.0×10⁻⁸ Torr, preferably about 3.0×10⁻⁸ Torr to 6.0×10⁻⁸ Torr, and more preferably about 4.5×10⁻⁸ Torr. The flux range of the non-metal source E2b is about 2.0×10⁻⁷ Torr to 8.0×10⁻⁷ Torr, preferably about 3.5×10⁻⁷ Torr to 6.0×10⁻⁷ Torr, and more preferably about 4.5×10⁻⁷ Torr to 5.5×10⁻⁷ Torr (e.g., 4.9×10⁻⁷ Torr). Under these conditions, the flux ratio of the non-metal source (Se) to the metal source (Ga) is maintained at about 8 to 15, preferably about 10 to 13, and more preferably about 11.

Under the above conditions, the second epitaxy process is performed for about 30 minutes to 120 minutes, preferably about 45 minutes to 75 minutes, and more preferably about 60 minutes, to form the second epitaxial film 2 composed of a multilayered two-dimensional semiconductor structure.

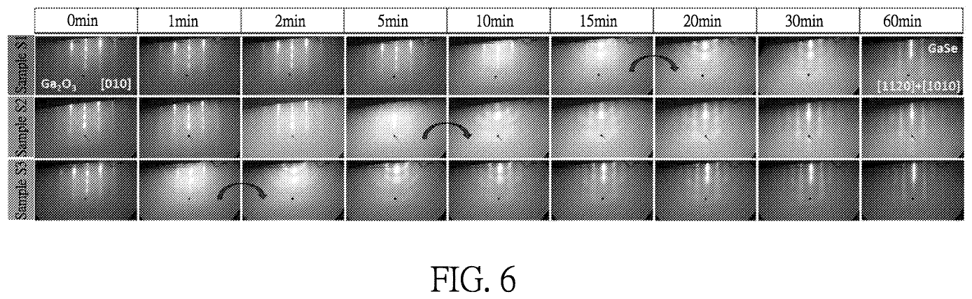

In one specific embodiment, real-time monitoring using reflection high-energy electron diffraction (RHEED) shows that, under the surface pretreatment condition, the nucleation delay time of the GaSe film is significantly shortened to about 3 minutes and preferably within 1 minute (as shown in FIG. 6). A continuous and clear streaky diffraction pattern is observed, confirming rapid nucleation and subsequent orderly layered growth behavior.

After the second epitaxial film 2 is formed, a cooling rate ranging from about 10 °C/min to 30 °C/min, preferably about 12 °C/min to 20 °C/min, and more preferably about 15 °C/min, can be adopted to facilitate stress release of the epitaxial film and to improve the stability of crystal quality.

The in-plane lattice constant of the second epitaxial film 2 along the b-axis direction ranges from about 3.6 Å to 4.0 Å, preferably about 3.7 Å to 3.9 Å, and more preferably about 3.785 Å, which corresponds to that of the first epitaxial film 1 (the three-dimensional semiconductor material) having an in-plane lattice constant along the b-axis direction of about 3.04 Å, indicating that the two materials have certain lattice matching compatibility. The bandgap of the second epitaxial film 2, measured at a low temperature of 25 K, ranges from 1.7 eV to 2.1 eV, preferably from about 1.75 eV to 1.85 eV, and more preferably from about 1.76 eV to 1.81 eV, which can exhibit a redshift of about 30 meV through strain-induced effects.

In addition, subsequent analyses, such as transmission electron microscopy (TEM) and photoluminescence (PL) analyses, confirm that when the two-dimensional semiconductor material, such as GaSe, nucleates on the metal-terminated surface, a non-metal passivation layer is generated, which contains the same non-metal element as the two-dimensional semiconductor material, such as selenium (Se). The thickness of the non-metal passivation layer is approximately at a single-layer to sub-single-layer level, which provides significant passivation effects on the metal-terminated layer on the surface of Ga₂O₃ layer, effectively reducing the interface defect density and improving the interface integrity and carrier transport characteristics of the heterogeneous structure.

In summary, the process conditions and method of the second epitaxy process effectively achieve the growth of a high-quality two-dimensional layered GaSe film and enable the formation of a mixed-dimensional heterogeneous structure with the Ga₂O₃ layer of the first epitaxial film, exhibiting excellent interface cleanliness, lattice matching, and optoelectronic performance.

### Heterogeneous Semiconductor Structure

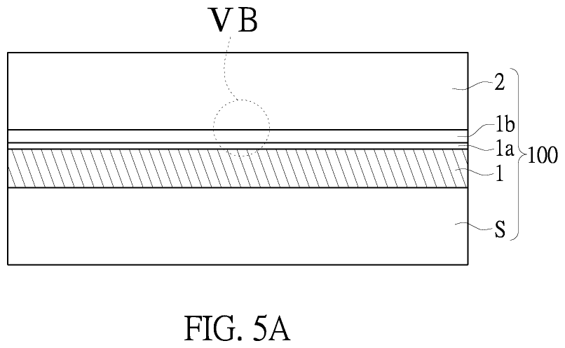

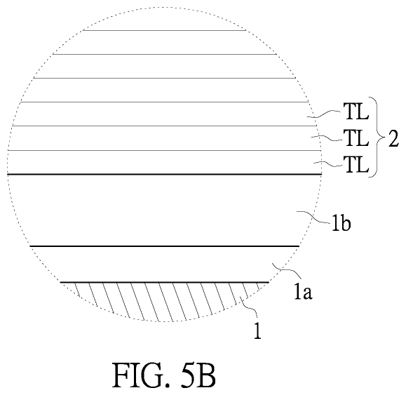

Furthermore, referring to FIG. 5A and FIG. 5B, the embodiment of the present disclosure also provides a heterogeneous semiconductor structure 100, which includes a substrate S, a first epitaxial film 1 formed on the substrate S and composed of a three-dimensional semiconductor material such as Ga₂O₃, and a second epitaxial film 2 formed on the first epitaxial film 1 and composed of a two-dimensional semiconductor material such as GaSe. The heterogeneous semiconductor structure 100 can further optionally include a metal-terminated layer 1a, such as a gallium metal-terminated layer, and a non-metal passivation layer 1b, such as a selenium passivation layer, formed between the first epitaxial film 1 and the second epitaxial film 2. The metal-terminated layer 1a is formed on the first epitaxial film 1, and the non-metal passivation layer 1b is formed on the metal-terminated layer 1a and beneath the second epitaxial film 2.

In terms of thickness, the first epitaxial film 1 (e.g., a three-dimensional semiconductor material layer composed of gallium oxide Ga₂O₃) has a thickness of about 20 nm to about 50 nm, preferably about 28 nm to about 45 nm, and more preferably about 30 nm to about 40 nm.

The second epitaxial film 2 (e.g., a gallium selenide GaSe layer composed of a two-dimensional semiconductor material and formed as a multilayered stacked structure) has a total thickness of about 50 nm to about 120 nm, preferably about 70 nm to about 100 nm, and more preferably about 80 nm to about 90 nm. In high-resolution transmission electron microscopy (HRTEM) analysis, the second epitaxial film 2 can be clearly identified as being composed of multiple two-dimensional tetralayer (TL) structural units stacked together, with a monolayer thickness of about 0.50 nm to 1.0 nm (e.g., about 0.8 nm). The second epitaxial film 2 includes approximately 80 to 130 layers of two-dimensional structural units TL, and more preferably about 90 to 120 layers.

Furthermore, a non-metal passivation layer 1b is formed between the first epitaxial film 1 and the second epitaxial film 2. The non-metal passivation layer 1b is formed during the initial stage of the second epitaxy process through the reaction between non-metal atoms, such as selenium (Se), and the metal element of the metal-terminated layer, such as gallium (Ga), on the surface of the first epitaxial film. The non-metal passivation layer primarily consists of a non-metal element identical to that of the two-dimensional semiconductor material and forms a stable interfacial bonding layer.

According to high-resolution transmission electron microscopy (HRTEM) analysis, the non-metal passivation layer 1b has a thickness of about 0.3 nm to 1.0 nm, preferably about 0.4 nm to 0.8 nm, and more preferably about 0.5 nm to 0.7 nm, corresponding approximately to a sub-single-layer to single-layer atomic thickness. The non-metal passivation layer 1b effectively terminates unsaturated bonds at the interface between the first epitaxial film 1 and the second epitaxial film 2, reduces the interface defect density, and further improves the nucleation rate, film quality, and carrier transport characteristics of the subsequent two-dimensional semiconductor material.

By the above process conditions, continuous epitaxial growth of the two-dimensional and three-dimensional semiconductor materials can be achieved under ultra-high-vacuum conditions. As a result, a mixed-dimensional (i.e., two-dimensional/three-dimensional) heterogeneous semiconductor structure is successfully fabricated, exhibiting excellent lattice matching, interface quality, material uniformity, and tunable optoelectronic properties. This structure could effectively enhance device photoresponsivity, photoelectric conversion efficiency, and self-powered photodetection capability, and has potential for application in wafer-level device fabrication.

To further illustrate the method for manufacturing the heterogeneous semiconductor structure described in the present disclosure, several exemplary process demonstrations under different conditions are provided below. Although the present disclosure is not limited to specific parameters or equipment configurations, the illustrated process examples are implemented using a plasma-assisted molecular beam epitaxy (PA-MBE) system under ultra-high-vacuum conditions and demonstrate the differences between processes with and without the surface pretreatment step.

### Process Example 1: Sample S1, Without Surface Pretreatment

First, a sapphire substrate with a c-plane crystal orientation (c-sapphire) is placed into the vacuum epitaxy system. The chamber is evacuated to about 10⁻¹⁰ Torr, and the substrate is heated to 450 °C at a rate of about 10 °C/min. Subsequently, a radio-frequency (RF) oxygen plasma is introduced, with the RF power set to 300 W and the oxygen flow rate set to 1.0 sccm. At the same time, the gallium (Ga) atomic beam source flux is set to 2.0×10⁻⁸ Torr for an epitaxy duration of 60 minutes, thereby forming a β-Ga₂O₃ film layer with a thickness of about 32 nm on the substrate. The substrate is then cooled at a rate of about 20 °C/min to about 60 °C. Next, the substrate is reheated to 480 °C at a rate of about 10 °C/min. After the substrate temperature stabilizes, the Ga flux is set to about 4.5×10⁻⁸ Torr and the Se flux to about 4.9×10⁻⁷ Torr, with a Se/Ga flux ratio of approximately 11, and a GaSe film layer is grown for 60 minutes. Finally, the substrate is cooled at a rate of about 15 °C/min to room temperature to complete the preparation of sample S1.

### Process Example 2: Sample S2, Without Surface Pretreatment

The process conditions for sample S2 are generally the same as those for sample S1, except for the substrate temperature setting during the second epitaxy process. First, following the same procedure as in S1, a β-Ga₂O₃ film layer with a thickness of about 32 nm is formed, and the substrate is cooled to about 60 °C. The substrate is then reheated to 425 °C at a rate of about 10 °C/min. After the substrate temperature stabilizes, the Ga flux (4.5×10⁻⁸ Torr) and Se flux (4.9×10⁻⁷ Torr, with a Se/Ga flux ratio of approximately 11) are activated to perform GaSe epitaxy for 60 minutes. Finally, the substrate is cooled at a rate of about 15 °C/min to room temperature to complete the preparation of sample S2.

### Process Example 3: Sample S3, With Surface Pretreatment

First, following the same procedure as in S1 and S2, a β-Ga₂O₃ film layer with a thickness of about 32 nm is formed on a c-sapphire substrate, and the substrate is cooled to about 60 °C. Then, the substrate is reheated at a rate of about 10 °C/min to 425 °C. At this temperature, the Ga atomic beam source is activated with a flux of about 4.5×10⁻⁸ Torr for about 5 minutes to perform surface pretreatment, allowing Ga atoms to deposit on the surface of the Ga₂O₃ film. Subsequently, the substrate is heated at a rate of about 15 °C/min to about 600 °C and maintained at this temperature for about 10 minutes for annealing treatment, followed by cooling at a rate of about 15 °C/min back to a substrate temperature of 425 °C. After the temperature stabilizes, the Ga flux (4.5×10⁻⁸ Torr) and Se flux (4.9×10⁻⁷ Torr, with a Se/Ga flux ratio of approximately 11) are activated to perform GaSe epitaxy for 60 minutes. Finally, the substrate is cooled at a rate of about 15 °C/min to room temperature to complete the preparation of sample S3.

### In-Situ Reflection High-Energy Electron Diffraction (RHEED) Analysis

The epitaxial growth behavior of GaSe on the Ga₂O₃ film in the above process examples 1 to 3 is analyzed using in-situ reflection high-energy electron diffraction (RHEED) to observe the effects of different epitaxy conditions on GaSe nucleation and growth quality.

As shown in FIG. 6, under higher temperature conditions (e.g., 480 °C, sample S1), a nucleation delay phenomenon is observed, which takes about 15 to 20 minutes for the diffraction pattern to gradually change from a blurred pattern to a clear streaky pattern. Under a lower epitaxy temperature condition (e.g., 425 °C, sample S2), the nucleation time of GaSe is shortened to about 5 to 10 minutes, indicating that a lower temperature enhances the nucleation efficiency.

In comparison, in the preferred embodiment (sample S3), by performing the surface pretreatment process (Ga pretreatment) to form a metal-terminated surface (Ga-terminated surface) on the Ga₂O₃ surface, the nucleation behavior of GaSe is further significantly improved. According to the real-time RHEED observation, under this condition, the GaSe film rapidly completes nucleation within about 1 to 2 minutes, showing clear and distinct streaky diffraction patterns and maintaining good layered growth behavior.

In addition, for sample S3 after Ga pretreatment, the in-plane lattice constant of the GaSe layer, as analyzed by RHEED, is approximately 3.785 Å, confirming good two-dimensional layered crystallinity with significantly improved uniformity and surface coverage.

### Photoluminescence (PL) Analysis

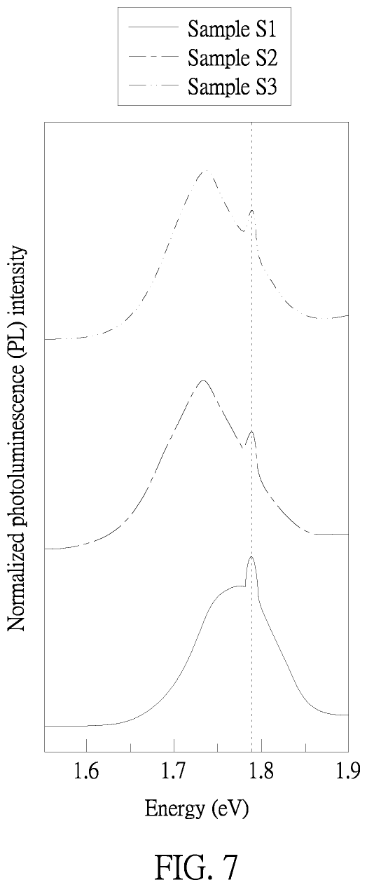

As shown in FIG. 7, photoluminescence (PL) analysis is performed at a low temperature of 25 K to compare the PL signals among sample S1 (480 °C without pretreatment), sample S2 (425 °C without pretreatment), and sample S3 (425 °C with Ga surface pretreatment).

The main PL peak of sample S1 (480 °C) appears at approximately 1.77 eV with a broad signal profile. Shoulder peaks are observed at approximately 1.76 eV and 1.81 eV, which are attributed to bound excitons and free excitons, respectively.

The main PL peak of sample S2 (425 °C) appears at approximately 1.78 eV, showing a redshift of about 30 meV compared with S1. This indicates that the lower growth temperature introduces strain-induced effects, which effectively tunes the bandgap characteristics of the GaSe film.

Sample S3 (425 °C with Ga pretreatment) also exhibits a main peak at approximately 1.78 eV, similar to that of S2, indicating that the Ga pretreatment condition does not significantly change the main peak energy position. However, the PL signal of S3 is clearer and stronger, demonstrating that Ga pretreatment further improves crystal quality, reduces defect density, and enhances luminescence efficiency.

### High-Resolution Transmission Electron Microscopy (HRTEM) Analysis

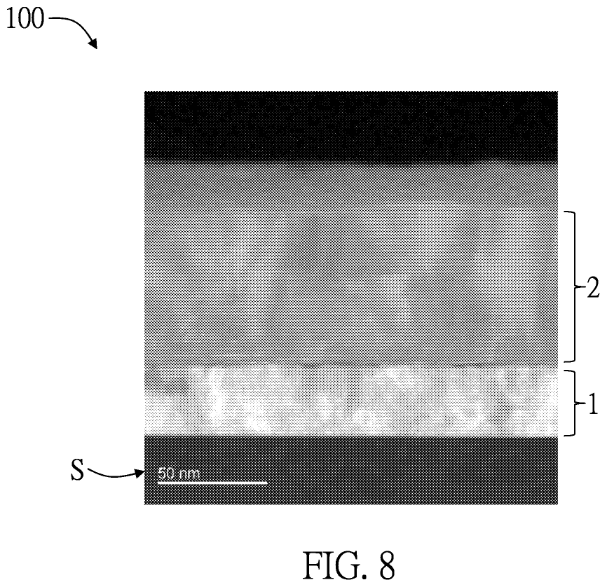

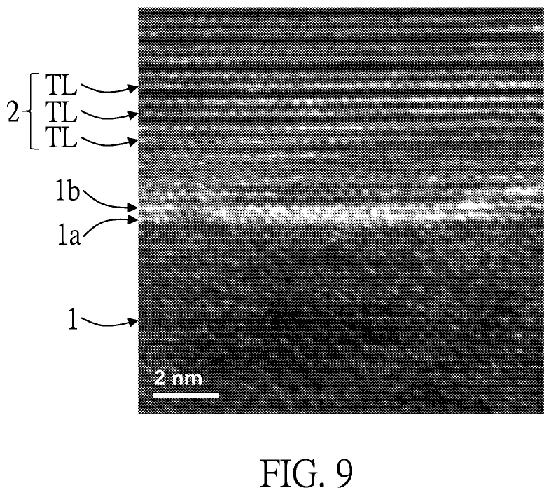

As shown in FIG. 8 and FIG. 9, high-resolution transmission electron microscopy (HRTEM) analysis of sample S3 (425 °C, with Ga pretreatment) reveals a clear and distinct heterogeneous junction structure at the interface between the first epitaxial layer 1 (Ga₂O₃) and the second epitaxial layer 2 (GaSe). This structure is attributed to the formation of a non-metal passivation layer 1b (Se passivation layer) between the first epitaxial layer 1 (Ga₂O₃) and the second epitaxial layer 2 (GaSe), with a thickness of about 0.4 nm to 0.8 nm. The non-metal passivation layer 1b provides a well-defined compositional transition and a stable bonding interface structure between the layers.

Furthermore, high-resolution imaging confirms that the GaSe film layer above the Se passivation layer exhibits a clear multilayered structure composed of multiple two-dimensional TL structural units. The GaSe layer demonstrates typical two-dimensional crystalline characteristics, and distinct van der Waals gaps between the layers are clearly visible. This evidence confirms that the GaSe layer is epitaxially grown on the Ga₂O₃ layer in a layered stacking manner. The layers (the two-dimensional TL structural units) in the second epitaxial layer 2 are regularly arranged without noticeable dislocations or defects, indicating a highly ordered epitaxy process.

Based on the HRTEM analysis shown in FIG. 8 and FIG. 9, the first epitaxial film 1 (Ga₂O₃) formed in sample S3 has a thickness of about 30 nm to 40 nm, and the second epitaxial film 2 (GaSe) has a thickness of about 80 nm to 90 nm, corresponding to more than 100 layers of two-dimensional structural units TL. The non-metal passivation layer 1b (Se passivation layer) located between the two films has a thickness of about 0.5 nm to 0.7 nm, corresponding to a single-layer to sub-single-layer structure, which exhibits excellent structural stability and interfacial integrity.

These analysis results indicate that Ga surface pretreatment forms a Ga-terminated surface on the Ga₂O₃ layer and further generates a Se passivation layer, thereby achieving high-quality heterogeneous integration between the two-dimensional and three-dimensional semiconductor materials. This configuration effectively reduces interface defects and dislocation density while ensuring high-quality epitaxial characteristics of the overall structure.

### Applications of the Heterogeneous Semiconductor Structure

The heterogeneous semiconductor structure of the embodiment of the present disclosure can be applied, for example, to a self-powered broadband photodetector. Specifically, a P-N heterojunction composed of two-dimensional gallium selenide (GaSe) and three-dimensional gallium oxide (Ga₂O₃) covers a wide spectral range, with the bandgaps of the two materials spanning from the visible region (approximately 1.78 eV) to the deep ultraviolet region (approximately 4.96 eV). The P-N heterojunction can generate an internal electric field without the need for an external bias voltage, effectively facilitating the separation of photogenerated carriers. The heterogeneous semiconductor structure of the present embodiment exhibits high responsivity and high detectivity under zero-bias operation, which is suitable for devices requiring low-power, broadband optoelectronic sensing, environmental monitoring, and high-sensitivity military detection.

### Beneficial Effects of the Embodiments

The method and the heterogeneous semiconductor structure of the embodiment of the present disclosure include sequentially epitaxially growing a three-dimensional N-type semiconductor material (e.g., β-Ga₂O₃), and a two-dimensional P-type semiconductor material (e.g., GaSe) on an oxide single-crystal substrate (e.g., a sapphire substrate) to form a mixed-dimensional heterogeneous semiconductor structure with a well-defined interface.

Through the above technical approach, the embodiment of the present disclosure effectively improves the interface cleanliness and epitaxial quality between the two-dimensional and three-dimensional materials in the heterogeneous semiconductor structure. Compared with conventional transfer or exfoliation stacking methods, the method of the present embodiment significantly reduces interface defect density and enhances the bonding integrity of the heterogeneous structure. Furthermore, the embodiment of the present disclosure achieves a high-quality heterogeneous junction structure, which provides excellent electrical stability and photoresponse performance for subsequent optoelectronic applications, such as self-powered photodetectors.

In particular, the introduction of the surface pretreatment process in the embodiment (i.e., performing Ga evaporation deposition and annealing on the surface of the first epitaxial film) significantly enhances the quality and uniformity of the subsequent GaSe epitaxy.

The embodiment of the present disclosure solves common problems in conventional heterogeneous structures, such as high interface defect density, difficulty in epitaxial nucleation, and interlayer misalignment. By introducing a metal-terminated layer and forming a non-metal passivation layer, the epitaxial surface free energy is effectively altered, nucleation uniformity is promoted, and a stable bonding interface is formed. As a result, high-quality and low-defect two-dimensional/three-dimensional heterogeneous epitaxial structures are achieved with good lattice matching and layered stacking characteristics. The heterogeneous semiconductor structure can be further applied to highly sensitive, self-powered optoelectronic devices to improve photoresponse efficiency and device reliability.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a heterogeneous semiconductor structure, comprising:
performing a first epitaxy process, including: using a vacuum epitaxy system to epitaxially form a first epitaxial film composed of a three-dimensional semiconductor material on a substrate under a vacuum condition ranging from 10⁻¹² Torr to 10⁻⁷ Torr; wherein the substrate is an oxide single crystal substrate, and the three-dimensional semiconductor material is an N-type semiconductor material having a three-dimensional crystal structure; and
performing a second epitaxy process, including: epitaxially forming a second epitaxial film composed of a two-dimensional semiconductor material on the first epitaxial film within the vacuum epitaxy system while maintaining and without breaking the vacuum condition; wherein the two-dimensional semiconductor material is a P-type semiconductor material having a multilayer layered crystal structure.

2. The method according to claim 1, wherein the vacuum epitaxy system is a molecular beam epitaxy system, and the vacuum condition ranges from 10⁻¹¹ Torr to 10⁻⁹ Torr.

3. The method according to claim 1, wherein the oxide single crystal substrate is a sapphire single crystal substrate, the three-dimensional semiconductor material has a first bandgap ranging from 4.8 eV to 5.0 eV and an in-plane lattice constant along a b-axis direction ranging from 2.8 Å to 3.3 Å, the two-dimensional semiconductor material has a second bandgap ranging from 1.9 eV to 2.1 eV, and a relative difference of the in-plane lattice constant between the two-dimensional semiconductor material and the three-dimensional semiconductor material is not greater than 25%.

4. The method according to claim 1, further comprising performing a surface pretreatment process between the first epitaxy process and the second epitaxy process, wherein the surface pretreatment process includes, after the first epitaxy process, performing an evaporation deposition pretreatment on the first epitaxial film formed on the substrate by using a metal source to form a metal-terminated layer on a surface of the first epitaxial film.

5. The method according to claim 4, wherein metal atoms supplied from the metal source in the evaporation deposition pretreatment are identical to at least one metal element contained in the three-dimensional semiconductor material, and the metal atoms in the evaporation deposition pretreatment are bonded with oxygen atoms of the three-dimensional semiconductor material to form the metal-terminated layer.

6. The method according to claim 5, wherein the second epitaxy process is performed after the surface pretreatment process and includes forming the second epitaxial film on the metal-terminated layer; and forming a non-metal passivation layer between the first epitaxial film and the second epitaxial film.

7. The method according to claim 6, wherein the three-dimensional semiconductor material of the first epitaxial film is β-gallium oxide (β-Ga₂O₃), the metal atoms used in the evaporation deposition pretreatment are gallium (Ga), the two-dimensional semiconductor material of the second epitaxial film is gallium selenide (GaSe), and a non-metal element of the non-metal passivation layer is selenium (Se).

8. The method according to claim 1, wherein the first epitaxy process includes heating the substrate to a first epitaxy temperature ranging from 400 °C to 500 °C.

9. The method according to claim 8, wherein the first epitaxy process further includes activating oxygen by using a radio-frequency oxygen plasma source of the vacuum epitaxy system under the conditions of a radio-frequency power of 250 W to 350 W, an oxygen gas flow rate of 0.5 sccm to 2 sccm, a metal source of a gallium atomic source, a metal atomic flux between 1.0×10⁻⁸ Torr and 5.0×10⁻⁸ Torr, and an epitaxy time of 30 minutes to 120 minutes, to form the first epitaxial film, and wherein a surface roughness (RMS roughness) of the first epitaxial film is not greater than 1 nm.

10. The method according to claim 4, wherein, in the surface pretreatment process, the substrate is first heated to the metal deposition temperature ranging from 380 °C to 460 °C, and then activates the metal source to deposit for 1 minute to 10 minutes to form the metal-terminated layer.

11. The method according to claim 10, wherein a metal source flux in the evaporation deposition pretreatment ranges from 1.0×10⁻⁸ Torr to 8.0×10⁻⁸ Torr, the metal atoms used in the metal source are identical to the metal element of the three-dimensional semiconductor material, and the surface pretreatment process further heats the substrate from the evaporation deposition temperature to an annealing temperature ranging from 550 °C to 650 °C, maintains the annealing temperature for 5 minutes to 15 minutes, and then cools down to form the metal-terminated layer.

12. The method according to claim 1, wherein the second epitaxy process adjusts the substrate to a second epitaxy temperature ranging from 410 °C to 440 °C, and then activates a metal source and a non-metal source of the vacuum epitaxy system to perform epitaxy and form the second epitaxial film.

13. The method according to claim 12, wherein a metal source flux of the metal source ranges from 2.0×10⁻⁸ Torr to 8.0×10⁻⁸ Torr, a non-metal source flux of the non-metal source ranges from 2.0×10⁻⁷ Torr to 8.0×10⁻⁷ Torr, and a flux ratio between the non-metal source and the metal source is between 8 and 15, wherein the metal source is a gallium atomic beam source, the non-metal source is a selenium atomic beam source, and an epitaxy time of the second epitaxy process ranges from 30 minutes to 120 minutes.

14. The method according to claim 12, wherein, during the second epitaxy process, an in-situ reflection high-energy electron diffraction (RHEED) monitoring shows that a nucleation delay time during growth of the second epitaxial film is within 3 minutes.

15. A heterogeneous semiconductor structure, comprising:
a substrate, wherein the substrate is an oxide single crystal substrate;
a first epitaxial film formed on the substrate and composed of a three-dimensional semiconductor material, wherein the three-dimensional semiconductor material is an N-type semiconductor material having a three-dimensional crystal structure; and
a second epitaxial film formed on the first epitaxial film and composed of a two-dimensional semiconductor material, wherein the two-dimensional semiconductor material is a P-type semiconductor material having a multilayer layered crystal structure.

16. The heterogeneous semiconductor structure according to claim 15, wherein the oxide single crystal substrate is a sapphire single crystal substrate, the three-dimensional semiconductor material has a first bandgap ranging from 4.8 eV to 5.0 eV and an in-plane lattice constant along a b-axis direction ranging from 2.8 Å to 3.3 Å, and the two-dimensional semiconductor material has a second bandgap ranging from 1.9 eV to 2.1 eV, wherein a relative difference of the in-plane lattice constant between the two-dimensional semiconductor material and the three-dimensional semiconductor material is not greater than 25%.

17. The heterogeneous semiconductor structure according to claim 15, further comprising:
a metal-terminated layer formed between the first epitaxial film and the second epitaxial film; and
a non-metal passivation layer formed between the first epitaxial film and the second epitaxial film,
wherein the metal-terminated layer is formed on the first epitaxial film, and the non-metal passivation layer is formed on the metal-terminated layer and is located beneath the second epitaxial film,
wherein a metal element of the metal-terminated layer is identical to a metal element of the three-dimensional semiconductor material, and a non-metal element of the non-metal passivation layer is identical to a non-metal element of the two-dimensional semiconductor material.

18. The heterogeneous semiconductor structure according to claim 17, wherein the first epitaxial film has a thickness ranging from 20 nm to 50 nm, the second epitaxial film is formed by a plurality of two-dimensional structural units stacked to each other and has a total thickness ranging from 50 nm to 120 nm, each of the two-dimensional structural units has a thickness ranging from 0.50 nm to 1.0 nm, and the non-metal passivation layer has a thickness ranging from 0.3 nm to 1.0 nm.
